(19) United States
(12) Patent Application Publication
(10) Pub. No.: US 2010/0224235 A1
(43) Pub. Date: Sep. 9, 2010

(54) LIGHT WEIGHT SOLAR CELL MODULES

(75) Inventors: NAOTO TAKAGI, Yokohama (JP); JUN KOISHIKAWA, Sagamihara City (JP); KRISTOF PROOST, Hemiksem (BE); JANE KAPUR, Kennett Square, PA (US); CHARLES ANTHONY SMITH, Vienna, WV (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/719,352

(22) Filed: Mar. 8, 2010

Related U.S. Application Data
(60) Provisional application No. 61/258,753, filed on Nov. 6, 2009.
(60) Provisional application No. 61/183,796, filed on Jun. 3, 2009.
(60) Provisional application No. 61/157,989, filed on Mar. 6, 2009.

(51) Int. Cl. H01L 31/048

(52) U.S. Cl. 136/251

(57) ABSTRACT

Provided herein are light weight solar cell modules having an ionomeric encapsulant sheet and at least one glass sheet. In particular, the weight of the solar cell modules is reduced by reducing the thickness of the at least one glass sheet to about 2.0 mm or less, or to about 1.5 mm or less. The light weight modules retain favorable performance properties such as good pummel adhesion levels, good moisture resistance, and low stress. Further provided are lightweight solar cell modules equipped with integral mounting devices.

### CROSS-REFERENCE TO RELATED APPLICATIONS

This application claims priority under 35 U.S.C. §120 to U.S. Provisional Appln. Nos. 61/157,989, filed on Mar. 6, 2009; 61/183,796, filed on Jun. 3, 2009, and 61/258,753, filed on Nov. 6, 2009, each of which is incorporated herein by reference in its entirety.

### FIELD OF THE INVENTION

The present invention is directed to light weight solar cell modules comprising thin glass sheets and ionomeric encapsulants. In particular, the weight of the solar cell modules is reduced by reducing the thickness of at least one glass layer to 2.0 mm or less, or to 1.5 mm or less. Light weight solar cell modules may be used in light weight frames, or in frameless mounting systems.

### BACKGROUND OF THE INVENTION

Several patents, patent applications and publications are cited in this description in order to more fully describe the state of the art to which this invention pertains. The entire disclosure of each of these patents, patent applications and publications is incorporated by reference herein.

The use of solar cells is expanding rapidly because they provide a sustainable energy resource. Solar cells can typically be categorized into two types based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of self-supporting wafers (or cells) that are soldered together. The wafers generally have a thickness of between about 180 and about 240 μm. A panel of soldered solar cells, along with a layer of conductive paste and/or electrical wirings such as conducting wires and bus bars deposited thereon, is often referred to as a solar cell layer or assembly.

To form a weather resistant module that may be used for at least 20 years, the solar cell assembly is typically sandwiched or laminated between polymeric encapsulant layers or sheets. These front and back sheets insulate the solar cells from the environment and provide mechanical support to the module. Therefore, they are also referred to as outer protective layer sheets.

This three-layer structure is in turn sandwiched or laminated between outer protective layers or sheets. In general, a solar cell module derived from wafer-based solar cell(s) has a laminate structure comprising, in order of position from the front sun-facing side to the back non-sun-facing side: (1) a front outer protective layer or “front sheet,” (2) a front encapsulant layer, (3) a solar cell assembly or layer, (4) a back encapsulant layer, and (5) a back outer protective layer or “back sheet.”

In modules having this structure, it is essential that the materials positioned towards the sun-facing side of the solar cell assembly, i.e., the front sheet and the front encapsulant layer, have good transparency to allow sufficient sun light to reach the solar cells. In addition, some modules may comprise bi-facial solar cells. Bi-facial solar cells are able to generate electrical power by receiving sunlight directly on their sun-facing side and also by receiving sunlight that is reflected back to the opposite side, although it does not face the sun. Plainly, in bifacial modules it is essential that the materials surrounding both faces of the solar cells assembly be sufficiently transparent.

The front and back encapsulant sheets are typically made of polymeric materials, such as acid copolymers, ionomers, poly(ethylene vinyl acetates) (EVA), poly(vinyl acetals) (e.g., poly(vinyl butyrals) (PVB)), polyurethanes, poly(vinyl chlorides), polyethylenes (e.g., linear low density polyethylenes), polyolefin block copolymer elastomers, copolymers of α-olefins and α,β-ethylenically unsaturated carboxylic acid esters) (e.g., ethylene methyl acrylate copolymers and ethylene butyl acrylate copolymers), silicone elastomers, epoxy resins, and combinations of two or more of these polymeric materials. Among them, EVA has been the most popular choice for the solar cell encapsulant material.

Glass and flexible metal or plastic films have been used as the front and back protective layers in wafer-based solar cell modules. Glass remains the most desirable choice, however, due to its mechanical and optical properties.

Thin film solar cells have become an increasingly important alternative to wafer-based solar cells. The materials commonly used for such cells include amorphous silicon (a-Si), microcrystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, organic semiconductors, and the like. By way of example, thin film solar cells are described in U.S. Pat. Nos. 5,507,881; 5,512,107; 5,948,176; 5,994,163; 6,040,521; 6,123,824; 6,137,048; 6,288,325; 6,258,620; 6,613,603; and 6,784,301; and U.S. Patent Publication Nos. 20070298590; 20070281090; 20070240759; 20070232057; 20070238285; 20070227578; 20070209699; 20070079866; 20080223436; and 20080271675, for example.

A thin film solar cell assembly typically comprises a substrate. Multiple layers of light absorbing and semiconductor materials are deposited on the substrate. The substrate may be glass or a flexible film. It may also be referred to as a superstrate in those modules where it faces toward the sunlight. The thin film solar cell assemblies may further comprise conductive coatings, such as transparent conductive oxides (TCO) or electrical wirings, that are deposited on the semiconductor materials. Similarly to the wafer-based solar cell assemblies, the thin film solar cell assembly may be sandwiched or laminated between polymeric encapsulant layers, and this structure in turn may be sandwiched or laminated between outer protective layers.

The thin film solar cell assembly may have only one surface, specifically the surface opposite from the substrate or superstrate, laminated to a polymeric encapsulant layer. In these solar cell modules, the encapsulant layer is most often in contact with and laminated to an outer protective layer. For example, the thin film solar cell module may have a lamination structure comprising, in order of position from the front or sun-facing side to the back or non-sun-facing side, (1) a thin film solar cell assembly having a superstrate on its front sun-facing side, (2) a polymeric back encapsulant layer, and (3) a back protective layer or “back sheet.” In this structure, the superstrate performs the functions of the front protective layer.

Alternatively, the thin film solar cell module may have a laminated structure comprising, in order of position from the front or sun-facing side to the back or non-sun-facing side, (1) a front protective layer or “front sheet,” (2) a polymeric front encapsulant sheet, and (3) a thin film solar cell assembly having a substrate on its back or non-sun-facing side. In this structure, the substrate also performs the functions of the back protective layer.

In the past, to provide solar cell modules with sufficient strength, it has been necessary to use glass sheets with a significant thickness, e.g., about 2 mm or more. A recent trend, however, is to integrate solar cell modules into a building structure. For example, the solar cell modules may be part of a side window, or they may be mounted on a building roof. In such structures, it would be advantageous to reduce the weight of the modules while maintaining acceptable penetration strength and adhesion. Therefore, there is a need to reduce the weight of the solar cell modules, while maintaining a high degree of shatter resistance and mechanical strength.

Moreover, when solar cell modules are installed and used in building structures, they are often fixed within a frame and mounted on a support structure. The frames are commonly made of rigid materials such as metals or plastics. Metal frames have been made from steel, aluminum, titanium, brass, lead, chrome, copper, and combinations or alloys of two or more of these metals, for example. Plastic frames have been made from polycarbonate, polyurethane, nylon, and combinations of two or more of these materials, for example. It is also desirable to reduce the weight of the frames and mounting systems.

Finally, it may be desirable to mount a frameless solar cell module. To be successful in a frameless end use, a solar cell module would need to have a light weight construction and superior moisture resistance and weather ability.

### SUMMARY OF THE INVENTION

Provided herein are light weight solar cell modules having an ionomeric encapsulant sheet and at least one glass sheet. In particular, the weight of the solar cell modules is reduced by reducing the thickness of the at least one glass sheet to about 2.0 mm or less, or to about 1.5 mm or less. The light weight modules retain favorable performance properties such as good pummel adhesion levels, good moisture resistance, and low stress. Further provided are lightweight solar cell modules equipped with integral mounting devices.

The advantages and features of novelty that characterize the invention are pointed out with particularity in the claims annexed hereto and forming a part hereof. For a better understanding of the invention, its advantages, and the objects obtained by its use, however, reference should be made to the drawings which form a further part hereof, and to the accompanying descriptive matter, in which there is illustrated and described one or more preferred embodiments of the invention.

### BRIEF DESCRIPTION OF THE DRAWINGS

FIG. 1 is a view in cross-section of a solar cell module comprising wafer-based solar cells.

FIG. 2 is a view in cross-section of a solar cell module comprising thin film solar cells.

FIG. 3A is a view in cross-section of a solar cell module comprising two mounting devices.

FIG. 3B is a plan view of a solar cell module comprising two mounting devices.

FIG. 4 is a view in cross-section of a solar cell module comprising two mounting devices.

FIG. 5 is a plan view of a solar cell module comprising four mounting devices.

FIG. 6 is a plan view of a solar cell module comprising four mounting devices.

### DETAILED DESCRIPTION OF THE INVENTION

The following definitions apply to the terms as used throughout this specification, unless otherwise limited in specific instances.

Moreover, unless otherwise defined, all technical and scientific terms used herein have the same meaning as commonly understood by one of ordinary skill in the art to which this invention belongs. In case of conflict, the present specification, including the definitions herein, will control.

Although methods and materials similar or equivalent to those described herein can be used in the practice or testing of the invention, suitable methods and materials are described herein.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

The term “or”, as used herein, is inclusive; more specifically, the phrase “A or B” means “A, B, or both A and B”. Exclusive “or” is designated herein by terms such as “either A or B” and “one of A or B”, for example.

In addition, the ranges set forth herein include their endpoints unless expressly stated otherwise in limited circumstances. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed.

Moreover, where a range of numerical values is recited herein, unless otherwise stated in specific circumstances, the range is intended to include the endpoints thereof, and all integers and fractions within the range. It is not intended that the scope of the invention be limited to the specific values recited when defining a range. Finally, when the term “about” is used in describing a value or an end-point of a range, the disclosure should be understood to include the specific value or end-point referred to.

When materials, methods, or machinery are described herein with the term “known to those of skill in the art”, or a synonymous word or phrase, the term signifies that materials, methods, and machinery that are conventional at the time of filing the present application are encompassed by this description. Also encompassed are materials, methods, and machinery that are not presently conventional, but that will have become recognized in the art as suitable for a similar purpose.

As used herein, the terms “comprises,” “comprising,” “includes,” “including,” “containing,” “characterized by,” “has,” “having” or any other synonym or variation thereof refer to a non-exclusive inclusion. For example, a process, method, article, or apparatus that is described as comprising a particular list of elements is not necessarily limited to those particularly listed elements but may further include other elements not expressly listed or inherent to such process, method, article, or apparatus.

The transitional phrase “consisting essentially of” limits the scope of a claim to the specified materials or steps and those that do not materially affect the basic and novel characteristic(s) of the claimed invention. “A ‘consisting essentially of’ claim occupies a middle ground between closed claims that are written in a ‘consisting of’ format and fully open claims that are drafted in a ‘comprising’ format.”

Where an invention or a portion thereof is described with an open-ended term such as “comprising,” it is to be understood that, unless otherwise stated in specific circumstances, this description also includes a description of the invention using the term “consisting essentially of” as they are defined above.

The indefinite articles “a” and “an” are employed to describe elements and components of the invention. The use of these articles means that one or at least one of these elements or components is present. Although these articles are conventionally employed to signify that the modified noun is a singular noun, as used herein the articles “a” and “an” also include the plural, unless otherwise stated in specific instances. Similarly, the definite article “the”, as used herein, also signifies that the modified noun may be singular or plural, again unless otherwise stated in specific instances.

As used herein, the term “copolymer” refers to polymers comprising copolymerized units or residues resulting from copolymerization of two or more comonomers. In this connection, a copolymer may be described herein with reference to its constituent comonomers or to the amounts of its constituent comonomers, for example “a copolymer comprising ethylene and 9 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

The term “acid copolymer” refers to a polymer comprising copolymerized units of an α-olefin, an α,β-ethylenically unsaturated carboxylic acid, and optionally other suitable comonomer(s), such as an α,β-ethylenically unsaturated carboxylic acid ester.

The term “ionomer” refers to a polymer that is produced by partially or fully neutralizing an acid copolymer as described above. More specifically, the ionomer comprises ionic groups that are metal ion carboxylates, for example, alkali metal carboxylates, alkaline earth metal carboxylates, transition metal carboxylates and mixtures of such carboxylates. Such polymers are generally produced by partially or fully neutralizing the carboxylic acid groups of precursor or parent polymers that are acid copolymers, as defined herein, for example by reaction with a base. An example of an alkali metal ionomer as used herein is a sodium ionomer (or sodium neutralized ionomer), for example a copolymer of ethylene and methacrylic acid wherein all or a portion of the carboxylic acid groups of the copolymerized methacrylic acid units are in the form of sodium carboxylates.

The term “laminate”, as used herein alone or in combined form, such as “laminated” or “lamination” for example, refers to a structure having at least two layers that are adhered or bonded firmly to each other. The layers may be adhered to each other directly or indirectly. “Directly” means that there is no additional material, such as an interlayer or an adhesive layer, between the two layers, and “indirectly” means that there is additional material between the two layers.

The materials, methods, and examples herein are illustrative only and, except as specifically stated, are not intended to be limiting.

Finally, all percentages, parts, ratios, and the like set forth herein are by weight, unless otherwise stated in specific instances.

Described herein is a solar cell module, which comprises as laminated layers: (A) a solar cell layer or assembly comprising one or more solar cells, (B) at least one encapsulant layer that comprises an ionomer composition and is laminated to one side of the solar cell assembly, and (C) at least one protective layer comprising a thin glass sheet with a thickness of less than 2 mm, preferably about 1.5 mm or less. The term “laminated”, as used herein, refers to two or more layers that are bonded either directly (i.e., without any additional material between the two layers) or indirectly (i.e., with additional material, such as interlayer or adhesive materials or primer, between the two layers). In one solar cell module, the at least one ionomer encapsulant layer has two sides, one of which is laminated to the solar cell assembly and the other side of which is laminated to the at least one thin glass out protective layer. In another solar cell module, the at least one ionomer encapsulant layer is directly bonded on one side to the solar cell assembly and on the other side to the at least one thin glass sheet outer protective layer.

It had been believed that solar cell modules do not possess adequate strength when fabricated with glass sheets having a thickness of 2 mm or less. It has now been found, however, that when the solar cell module includes an ionomeric encapsulant sheet, the thickness of the glass sheets may be reduced. Consequently, the weight of the solar cell module is reduced, and yet its strength and shatter resistant properties are maintained at an acceptable level. Accordingly, provided herein is a solar cell module that comprises one or more thin glass sheets and one or more ionomeric encapsulant sheets.

In addition, these lighter solar cell modules also enable the use of lighter frames and mounting systems. As used in this context, the term “lighter” may refer to the weight of the frame or mounting system. Alternatively, however, it may refer to the weight that the frame or mounting system is properly rated to support. Moreover, ionomeric encapsulant sheets have superior moisture resistance and weather ability. Therefore, solar cell modules made with thin glass sheets and ionomeric encapsulant sheets may also be suitable for use in frameless mounting systems.

Referring now to the drawings, wherein like reference numerals designate corresponding structure throughout the views, and referring in particular to

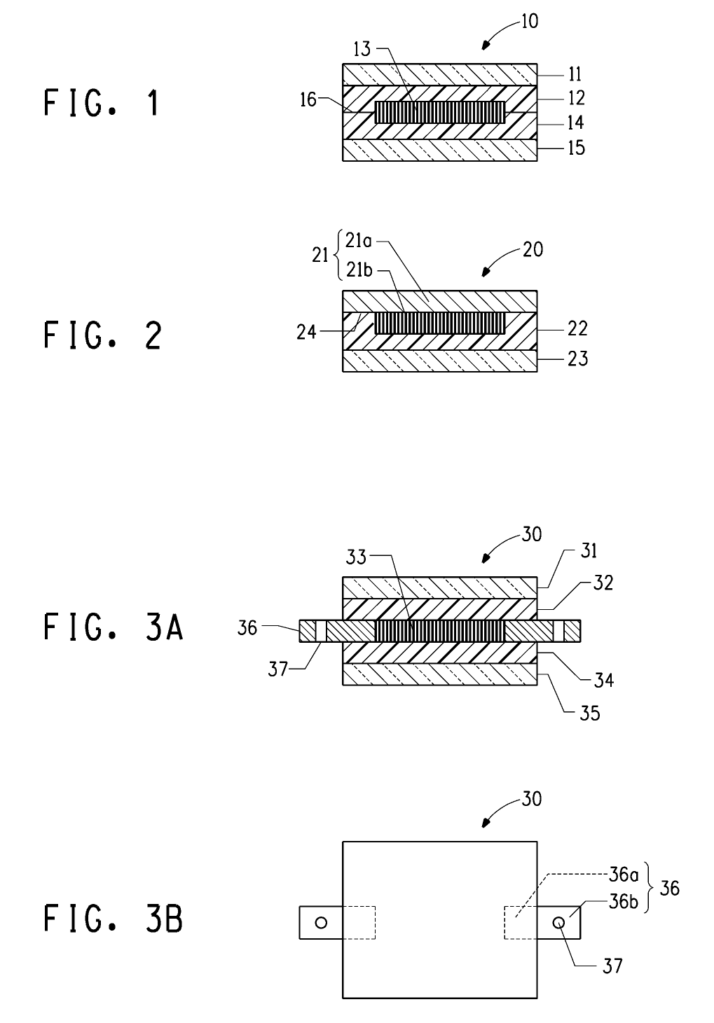

FIG. 1, a solar cell module 10 comprises a solar cell assembly 13 that is laminated between two polymeric encapsulant layers, a first or front encapsulant layer 12 and a second or back encapsulant layer 14. These three layers, in turn, are laminated between two outer protective layers, a first outer protective layer or front sheet 11 and a second outer protective layer or back sheet 15. One or both of the two encapsulant layers 12 and 14 is an ionomeric encapsulant layer, and one or both of the outer protective layers 11 and 15 is a thin glass sheet.

Still referring to FIG. 1, the solar cell assembly 13 has a lateral area that is smaller than the lateral area of the solar cell module 10. Thus, the two encapsulant layers 12 and 14 may come in contact and bond to each other to form a seal 16 around the edges of the solar cell assembly 13. Moreover, the first and second encapsulant layers 12 and 14 may be the same or different. In addition, the first and second protective layers 11 and 15 may be the same or different.

Referring now to FIG. 2, a solar cell module 20 comprises a solar cell assembly 21, which, in turn, comprises thin film solar cells 21b deposited on a substrate or superstrate 21a. Substrate or superstrate 21a is an outermost surface layer of the module. Generally, the thin film solar cell assembly 21 is laminated to an ionomer encapsulant layer 22 that is in contact with the solar cells 21b. The ionomeric encapsulant layer 22 is also laminated to a thin glass sheet that serves as the outer protective layer 23. Again, the thin films solar cells 21b have a lateral area that is smaller than the lateral area of the solar cell module 20 or of the substrate or superstrate 21a. Thus, the encapsulant layer 22 may come in contact with the substrate or superstrate 21a and bond to it to form a seal 24 around the edges of the solar cell assembly 21b.

Referring now to FIGS. 3A and 3B, a solar cell module 30 comprises a solar cell assembly 33 that is laminated between two encapsulant layers 32 and 34. These three layers, in turn, are laminated between two outer protective layers 31 and 35. Again, one of both of the two encapsulant layers 32 and 34 is an ionomeric encapsulant layer; one or both of the two outer protective layers 31 and 35 is a thin glass sheet; and the solar cell assembly 33 has a lateral area that is smaller than that of the solar cell module 30. Moreover, solar cell module 30 further comprises two mounting devices 36, each of which may be positioned at opposite side of the solar cell module 30. In particular, each mounting device 36 comprises a first portion 36a that is bonded to the two encapsulant layers 32 and 34 next to and outside the peripheral edges of the solar cell assembly 33 and a second portion 36b that is protruding outward from the peripheral edges of the solar cell module 30.

Any suitable material may be used in forming the mounting device(s) 36. More specifically, the mounting device 36 may be fabricated from any material(s) that are sufficiently durable to withstand the stress of supporting the solar cell module 30. In addition, the mounting device 36 must also be capable of withstanding any additional forces that may be applied to the solar cell module 30, such as for example the force of a wind, or the force of a pressure difference between the interior and exterior of a building. Accordingly, the at least one mounting device 36 may be made of a sufficiently tough metal, such as steel, aluminum, titanium, brass, lead, chrome, copper, or combinations or alloys of two or more of these metals. Alternatively, the at least one mounting device 36 may be made of a sufficiently tough plastic, such as polycarbonate, polyurethane, nylon, or a combination of two or more of these plastics.

Still referring to FIGS. 3A and 3B, there may be an anchoring means 37 comprised in the second portion of the mounting device 36b. Any type of anchoring means 37 that can be used to fix the solar cell module to a support structures can be used here. For example, as illustrated in FIGS. 3A and 3B, the anchoring means 37 may be a hole in the second portion 36b of the mounting device 36, which can be used to receive a screw to fix the module 30 onto a support structure. Other suitable anchoring means 37 include, without limitation, means similar to screws, such as nails and bolts. Anchoring means 37 that do not require a hole include a clamp or similar device that secures the solar cell module 30 to the frame via the mounting device 36. A clamp may be secured to the frame or to the mounting device 36; therefore, it may “clamp” the frame, or it may “clamp” the mounting device 36.

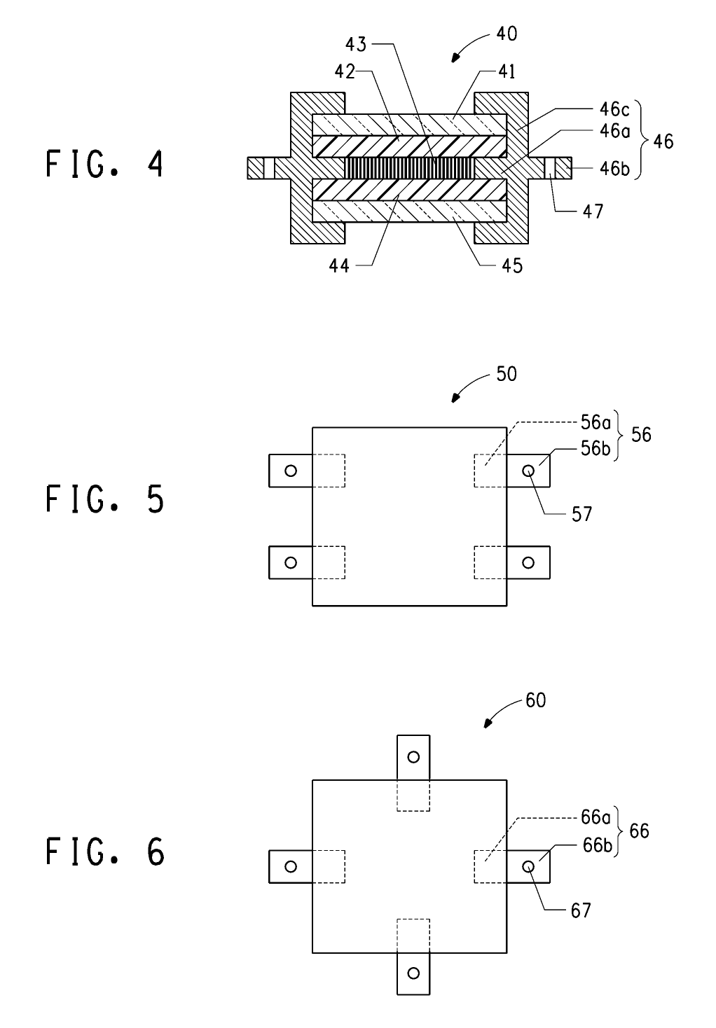

Referring now to FIG. 4, solar cell module 40 has a structure that is similar to the structure of solar cell module 30 depicted in FIGS. 3A and 3B. It includes two encapsulant layers 42 and 44, two outer protective layers 41 and 45, and mounting device 46 comprising a first portion 46a that is bonded to the two encapsulant layers 42 and 44 next to and outside the peripheral edges of the solar cell assembly 43 and a second portion 46b that is protruding outward from the peripheral edges of the solar cell module 40. Here again, second portion 46b is equipped with anchoring means 47, depicted as a hole in the second portion 46b of the mounting device 46. Mounting device 46, however, further comprises a third portion 46c that forms a cover over the peripheral edges of the solar cell module 40.

Clearly, if extended along all four edges of a quadrangular solar cell module 40, four mounting devices 46 would form a type of frame. In addition, extended mounting devices 46 may be equipped with a plurality of anchoring means 47. It is not necessary, however, for the mounting devices 46 to have this configuration, however. Like mounting devices 36 depicted in FIGS. 3A and 3B, mounting devices 46 depicted in FIG. 4 may have a size that is small relative to the length of the edges of the solar cell module 40. In addition, third portion 46c may form a cover over a portion of the peripheral edge that is equal to the portion from which mounting device 46 protrudes. Alternatively, third portion 46c may form a cover over a portion of the peripheral edge that is greater than or less than the portion from which mounting device 46 protrudes. Also clearly, a second type of frame is formed by a configuration of mounting devices 46 in which four cover portions 46c extend over the entirety of the peripheral edges, even though the mounting devices 46 have a length that is small compared to the length of the peripheral edges.

Referring now to FIG. 5, solar cell module 50 also has a structure that is similar to the structure of solar cell module 30 depicted in FIGS. 3A and 3B. It comprises a solar cell assembly and two ionomeric encapsulant sheets laminated between at least two glass sheets, one or both of which is a thin glass sheet. solar cell module 50, however, includes two pairs of mounting devices 56. The members of each pair are attached to opposite peripheral edges of the solar cell module 50. Moreover, mounting devices 56 also comprise a first portion 56a that is bonded to the ionomeric encapsulant layers and a second portion 56b that is protruding outward from the peripheral edges of the solar cell module 50. Here again, second portion 56b is equipped with anchoring means 57, depicted as a hole in the second portion 56b of the mounting device 56. Although not depicted in the Drawings, mounting devices 56 may have a structure similar to that of mounting devices 46 in solar cell module 40 shown in FIG. 4. In particular, they may also be equipped with a third portion that forms a cover over the peripheral edges of the solar cell module 50.

Referring now to FIG. 6, solar cell module 60 has a structure that is similar to the structure of solar cell module 30 depicted in FIGS. 3A and 3B. It comprises at least one ionomeric encapsulant sheet laminated between at least two glass sheets, one or both of which is a thin glass sheet. In addition, solar cell module 60 also includes two pairs of mounting devices 66, although these mounting devices are arranged in a different configuration from that depicted in FIG. 5. In solar cell module 60, one mounting device 66 is attached to each of the four peripheral edges of the solar cell module 60. Similarly to the other mounting devices 36, 46 and 56, mounting devices 66 also comprise a first portion 66a that is bonded to the ionomeric encapsulant and a second portion 66b that is protruding outward from the peripheral edges of the solar cell module 60. Here again, second portion 66b is equipped with anchoring means 67, depicted as a hole in the second portion 66b of the mounting device 66. Finally, although not depicted in the Drawings, mounting devices 66 may have a structure similar to that of mounting devices 46 in solar cell module 40 shown in FIG. 4. In particular, they may also be equipped with a third portion that forms a cover over the peripheral edges of the solar cell module 60.

The term “solar cell” as used herein refers to any article that can convert light into electrical energy. Suitable solar cells include, but are not limited to, wafer-based solar cells (e.g., solar cells comprising materials selected from c-Si, mc-Si, and mixtures thereof) and thin film solar cells (e.g., solar cells comprising materials selected from a-Si, μc-Si, CdTe, CIS, CIGS, light absorbing dyes, organic semiconductors, and mixtures thereof). A solar cell assembly may comprise one or a plurality of solar cells. The plurality of solar cells may be electrically interconnected or arranged in a flat plane. In addition, the solar cell assembly may further comprise conductive pastes in wafer-based solar cells, conductive coatings in thin film solar cells, or electrical wirings deposited upon either type of solar cells.

The solar cell assembly may have a front, sun-facing side and a back, non-sun-facing side. In such a configuration, all the laminated layers that are positioned between the light source and the front, sun-facing side of the solar cell assembly should have sufficient transparency to allow light to reach the solar cells. The other laminated layers positioned behind the back, non-sun-facing side of the solar cell assembly need not be transparent.

Alternatively, the solar cell layer may be bifacial. In solar cell modules comprising bifacial solar cell layers, all the laminated layers comprised in the module, with the exception of the solar cell assembly, should be sufficiently transparent to allow light or reflected light to reach the solar cells.

The term “thin glass sheet” as used herein refers to a glass sheet or film having a thickness of less than 2.0 mm, or about 1.9 mm or less, or about 1.8 mm or less, or about 1.7 mm or less, or about 1.6 mm or less, or about 1.5 mm or less, or about 1.2 mm or less, or about 1 mm or less, or about 0.8 mm or less, or about 0.1 to about 0.8 mm, or about 0.2 to about 0.7 mm, or about 0.2 to about 0.6 mm. They may be selected from any suitable types of glass sheets, such as block or rolled thin glass sheets. Some types of such thin glass sheets have been used as substrates for liquid crystal devices and are commercially available from, e.g., Praezisions Glas & Optik GmbH (Germany), Pilkington (Toledo, Ohio), Matsunami Glass Ind., Ltd. (Japan), Nippon Sheet Glass Company, Ltd. (Japan), Nippon Electric Glass Co., Ltd. (Japan), and Asahi Glass Co., Ltd. (Japan).

The ionomeric encapsulant sheet comprises an ionomer that is an ionic neutralized derivative of a precursor acid copolymer comprising copolymerized units of an α-olefin having 2 to 10 carbon atoms and about 18 to about 30 wt %, or about 20 to about 25 wt %, or about 21 to about 24 wt %, of copolymerized units of an α,β-ethylenically unsaturated carboxylic acid having 3 to 8 carbons, based on the total weight of the precursor acid copolymer.

Suitable α-olefin comonomers may include, but are not limited to, ethylene, propylene, 1-butene, 1-pentene, 1-hexene, 1-heptene, 3 methyl-1-butene, 4-methyl-1-pentene, and the like and mixtures of two or more thereof. In one preferred copolymer, the α-olefin is ethylene.

Suitable α,β-ethylenically unsaturated carboxylic acid comonomers may include, but are not limited to, acrylic acids, methacrylic acids, itaconic acids, maleic acids, maleic anhydrides, fumaric acids, monomethyl maleic acids, and mixtures of two or more thereof. In one preferred copolymer, the α,β-ethylenically unsaturated carboxylic acid is selected from acrylic acids, methacrylic acids, and mixtures of two or more thereof. In another preferred copolymer, the α,β-ethylenically unsaturated carboxylic acid is methacrylic acid.

The precursor acid copolymers may further comprise copolymerized units of one or more other comonomer(s), such as unsaturated carboxylic acids having 2 to 10, or preferably 3 to 8 carbons, or derivatives thereof. Suitable acid derivatives include acid anhydrides, amides, and esters. Esters are preferred. Specific examples of preferred esters of unsaturated carboxylic acids include, but are not limited to, methyl acrylates, methyl methacrylates, ethyl acrylates, ethyl methacrylates, propyl acrylates, propyl methacrylates, isopropyl acrylates, isopropyl methacrylates, butyl acrylates, butyl methacrylates, isobutyl acrylates, isobutyl methacrylates, tert-butyl acrylates, tert-butyl methacrylates, octyl acrylates, octyl methacrylates, undecyl acrylates, undecyl methacrylates, octadecyl acrylates, octadecyl methacrylates, dodecyl acrylates, dodecyl methacrylates, 2-ethylhexyl acrylates, 2-ethylhexyl methacrylates, isobornyl acrylates, isobornyl methacrylates, lauryl acrylates, lauryl methacrylates, 2-hydroxyethyl acrylates, 2-hydroxyethyl methacrylates, glycidyl acrylates, glycidyl methacrylates, poly(ethylene glycol) acrylates, poly(ethylene glycol)methacrylates, poly(ethylene glycol) methyl ether acrylates, poly(ethylene glycol) methyl ether methacrylates, poly(ethylene glycol) behenyl ether acrylates, poly(ethylene glycol) behenyl ether methacrylates, poly(ethylene glycol) 4-nonylphenyl ether acrylates, poly(ethylene glycol) 4-nonylphenyl ether methacrylates, poly(ethylene glycol) phenyl ether acrylates, poly(ethylene glycol) phenyl ether methacrylates, dimethyl maleates, diethyl maleates, dibutyl maleates, dimethyl fumarates, diethyl fumarates, dibutyl fumarates, dimethyl fumarates, vinyl acetates, vinyl propionates, and mixtures of two or more thereof. In one preferred copolymer, the suitable additional comonomers are selected from methyl acrylates, methyl methacrylates, butyl acrylates, butyl methacrylates, glycidyl methacrylates, vinyl acetates, and mixtures of two or more thereof. In another preferred copolymer, however, the precursor acid copolymer does not incorporate other additional comonomers.

Suitable precursor acid copolymers have a melt flow rate (MFR) of about 1 to about 1000 g/10 min, or about 20 to about 900 g/10 min, or about 20 to about 70 g/10 min, or about 70 to about 700 g/10 min, or about 100 to about 500 g/10 min, or about 150 to about 300 g/10 min, as determined in accordance with ASTM method D1238 at 190° C. and 2.16 kg.

Finally, suitable precursor acid copolymers may be synthesized as described in U.S. Pat. No. 3,404,134; 5,028,674; 6,500,888; or 6,518,365, for example.

To obtain the ionomers useful in the ionomeric encapsulant sheets, the precursor acid copolymers are partially neutralized by reaction with one or more bases. An example of a suitable procedure for neutralizing the parent acid copolymers is described in U.S. Pat. Nos. 3,404,134 and 6,518,365. After neutralization, about 5% to about 90%, or about 10% to about 60%, or about 20% to about 55%, of the hydrogen atoms of carboxylic acid groups present in the precursor acid are replaced by other cations. Stated alternatively, about 5% to about 90%, or about 10% to about 60%, or about 20% to about 55%, of the total content of the carboxylic acid groups present in the precursor acid copolymer are neutralized. In another alternative expression, the acid groups are neutralized to a level of about 5% to about 90%, or about 10% to about 60%, or about 20% to about 55%, based on the total content of carboxylic acid groups present in the precursor acid copolymers as calculated or measured for the non-neutralized precursor acid copolymers.

The ionomers comprise cations as counterions to the carboxylate anions. Suitable cations include any positively charged species that is stable under the conditions in which the ionomer composition is synthesized, processed and used. In some preferred ionomers, the cations used are metal cations, which may be monovalent, divalent, trivalent, multivalent, or mixtures thereof. Useful monovalent metal cations include but are not limited to cations of sodium, potassium, lithium, silver, mercury, copper, and the like, and mixtures thereof. Useful divalent metal cations include but are not limited to cations of beryllium, magnesium, calcium, strontium, barium, copper, cadmium, mercury, tin, lead, iron, cobalt, nickel, zinc, and the like, and mixtures thereof. Useful trivalent metal cations include but are not limited to cations of aluminum, scandium, iron, yttrium, and the like, and mixtures thereof. Useful multivalent metal cations include but are not limited to cations of titanium, zirconium, hafnium, vanadium, tantalum, tungsten, chromium, cerium, iron, and the like, and mixtures thereof. It is noted that when the metal cation is multivalent, complexing agents such as stearate, oleate, salicylate, and phenolate radicals may be included, as described in U.S. Pat. No. 3,404,134. In another preferred encapsulant, the metal cations used are monovalent or divalent metal cations. In yet another preferred encapsulant, the metal cations are selected from sodium, lithium, magnesium, zinc, potassium and mixtures thereof. In yet another preferred encapsulant, the metal cations are selected from cations of sodium, zinc and mixtures thereof. In yet another preferred encapsulant, the metal cation is sodium cation.

The resulting ionomer may have a MFR of 25 g/10 min or less, or about of 20 g/10 min or less, or about 10 g/10 min or less, or about 5 g/10 min or less, or about 0.7 to about 5 g/10 min, as determined in accordance with ASTM method D1238 at 190° C. and 2.16 kg.

The ionomeric encapsulant sheet may further contain other additives known within the art. The additives include, but are not limited to, processing aids, flow enhancing additives, lubricants, pigments, dyes, flame retardants, impact modifiers, nucleating agents, anti-blocking agents such as silica, thermal stabilizers, UV absorbers, UV stabilizers, dispersants, surfactants, chelating agents, coupling agents, reinforcement additives, such as glass fiber, fillers and the like. General information about suitable additives, suitable levels of the additives in the ionomeric encapsulants, and methods of incorporating the additives into the ionomeric encapsulants may be found in reference texts such as, for example, the Kirk Othmer Encyclopedia, the Modern Plastics Encyclopedia, McGraw-Hill (New York, 1995) or the Wiley Encyclopedia of Packaging Technology, 2d edition, A. L. Brody and K. S. Marsh, Eds., Wiley-Interscience (Hoboken, 1997). Four types of additives are of note for use in the ionomeric encapsulants, specifically thermal stabilizers, UV absorbers, hindered amine light stabilizers (HALS), and silane coupling agents. Further information about these four types of additives, such as preferred examples and suitable levels in ionomeric encapsulants, may be found in the reference texts cited above and in U.S. Pat. No. 7,641,965, for example.

Suitable ionomeric encapsulant sheets have a Young's modulus of about 200 to about 600 MPa, or about 250 to about 550 MPa, or about 300 to about 500 MPa, or about 300 to about 400 MPa, as determined in accordance with ASTM D5026 at 30° C. and 1 minute of load duration. Further, the ionomeric encapsulant sheet may have a total thickness of about 1 to about 120 mils (about 0.025 to about 3 mm), or about 5 to about 100 mils (about 0.127 to about 2.54 mm), or about 5 to about 45 mils (about 0.127 to about 1.14 mm), or about 10 to about 35 mils (about 0.25 to about 0.89 mm), or about 10 to about 30 mils (about 0.25 to about 0.76 mm). When a solar cell module includes more than one ionomeric encapsulant sheet, the thickness of each of the sheets is independently selected.

In addition, the ionomer sheets may have a smooth or rough surface on one or both sides prior to lamination. In one solar cell module, the ionomer sheet may have rough surfaces on both sides to facilitate de-airing during the lamination process. Rough surfaces can be created by mechanically embossing or by melt fracture during extrusion of the sheets followed by quenching so that surface roughness is retained during handling. The surface pattern can be applied to the sheet through common art-recognized processes. For example, the as-extruded sheet may be passed over a specially prepared surface of a die roll positioned in close proximity to the exit of the die which imparts the desired surface characteristics to one side of the molten polymer. Thus, when the surface of such a die roll has minute peaks and valleys, the polymer sheet cast thereon will have a rough surface on the side that is in contact with the roll, and the rough surface generally conforms respectively to the valleys and peaks of the roll surface. Such die rolls are described in, e.g., U.S. Pat. No. 4,035,549 and U.S. Patent Publication No. 20030124296. Again, the surface pattern of the ionomer sheets would disappear after the lamination process.

For example, the sheets may be formed through dipcoating, solution casting, compression molding, injection molding, lamination, melt extrusion casting, blown film, extrusion coating, tandem extrusion coating, or by any other procedures that are known to those of skill in the art. Preferably, the sheets are formed by an extrusion method, such as melt extrusion casting, melt coextrusion casting, melt extrusion coating, or tandem melt extrusion coating processes.

In those solar cell modules in which an ionomeric encapsulant layer is positioned at the front, sun-facing side of the solar cell assembly, the encapsulant layer should be sufficiently transparent to permit efficient operation of the module. Suitable front encapsulant layers preferably have a haze of about 1.5% or less, or about 1% or less, as determined in accordance with ASTM D1003. Alternatively, suitable ionomeric encapsulant layers may have a yellowness index (YI) of about 1.5 or less, or about 1 or less.

In addition to one or more solar cells, one or more thin glass sheets and one or more ionomeric encapsulant sheets, the solar cell modules may further comprise additional films, rigid sheets, or other non-ionomeric polymeric encapsulant sheets.

Suitable non-ionomeric materials for use in encapsulant layers such as 12 or 14 of FIG. 1 include, without limitation, ethylene unsaturated acid copolymers, polyethylene vinyl acetates) (EVA), poly(vinyl acetals) (e.g., poly(vinyl butyrals) (PVB)), polyurethanes, poly(vinyl chlorides), polyethylenes (e.g., linear low density polyethylenes), polyolefin block copolymer elastomers, copolymers of α-olefins and α,β-ethylenically unsaturated carboxylic acid esters) (e.g., ethylene methyl acrylate copolymers and ethylene butyl acrylate copolymers), silicone elastomers, epoxy resins, and blends or combinations of two or more of these materials.

Suitable sheets or films for use as one of the outer protective layers such as 11 or 15 of FIG. 1 include, without limitation, conventional glass sheets, plastic sheets, metal sheets, ceramic sheets, plastic films and metal films.

Suitable conventional glass sheets may have a thickness of about 2 mm or more and include not only window glass, plate glass, silicate glass, sheet glass, low iron glass, tempered glass, tempered CeO-free glass, and float glass, but also colored glass, specialty glass (such as those containing ingredients to control solar heating), coated glass (such as those sputtered with metals (e.g., silver or indium tin oxide) for solar control purposes), low E-glass, Toroglas® glass (Saint-Gobain N.A. Inc., Trumbauersville, Pa.), Solexia™ glass (PPG Industries, Pittsburgh, Pa.), but also Starphire® glass (PPG Industries).

Suitable plastic sheets comprise materials such as polycarbonates, acrylics, polyacrylates, cyclic polyolefins (e.g., ethylene norbornene polymers), polystyrenes (preferably metallocene-catalyzed polystyrenes), polyamides, polyesters, fluoropolymers, or combinations of two or more of these materials.

When a non-transparent sheet, such as aluminum, steel or galvanized steel, or a ceramic plate is used, it is used in a back protective layer or back sheet that is positioned towards the rear, non-sun-facing side of the solar cell assembly.

Suitable plastic film layers include, without limitation, polymers such as polyesters (e.g., poly(ethylene terephthalate) and poly(ethylene naphthalate)), polycarbonates, polyolefins (e.g., polypropylene, polyethylene, and cyclic polyolefins), norbornene polymers, polystyrenes (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetate, etc.), cellophanes, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers and the like) and combinations of two or more thereof. The plastic film may also be a bi-axially oriented polyester film (preferably poly(ethylene terephthalate) film) or a fluoropolymer film (e.g., Tedlar®, Tefzel®, and Teflon® films, from E. I. du Pont de Nemours and Company, Wilmington, Del. (DuPont)). Further the films used herein may be in the form of a multi-layer film, such as a fluoropolymer/polyester/fluoropolymer multilayer film (e.g., Tedlar®/PET/Tedlar® or TPT laminate film available from Isovolta AG., Austria or Madico, Woburn, Mass.).

When a non-transparent film, such as aluminum foil or a filled polymeric film is used, it is used in a back protective layer or back sheet that is positioned towards the rear, non-sun-facing side of the solar cell assembly.

When the solar cell assembly comprises thin film solar cells, the solar cell module also comprises a substrate or superstrate on which the thin film solar cells are deposited. Suitable substrates and superstrates are sheets and films that are described above as the outer protective layers, including the thin glass sheets. Suitable substrates and superstrates are also stable under the conditions under which the solar cells and solar cell assemblies are fabricated and operated.

The solar cell modules may further comprise other functional film or sheet layers embedded within the module. Such functional layers, such as, for example, dielectric layers or barrier layers, may comprise or may be derived from any of the polymeric films described above. In addition, the functional layers may be coated with additional functional coatings. For example, poly(ethylene terephthalate) films coated with a metal oxide coating, such as those described within U.S. Pat. Nos. 6,521,825 and 6,818,819 and European Patent No. EP1182710, may function as oxygen and moisture barrier layers in the solar cell modules.

If desired, a layer of nonwoven glass fiber (scrim) may also be included between the solar cell layers and the encapsulants to facilitate deaeration during the lamination process and/or to serve as reinforcement for the encapsulants. The use of such scrim layers is described within, e.g., U.S. Pat. Nos. 5,583,057; 6,075,202; 6,204,443; 6,320,115; and 6,323,416 and European Patent No. EP0769818.

If desired, one or both surfaces of the protective layers (i.e., the front and/or the back sheets), the encapsulant layers, and other layers incorporated within the solar cell module may be treated prior to the lamination process to enhance the adhesion to other laminate layers. This adhesion enhancing treatment may take any form known within the art and includes flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. Also, the adhesion strength may be further improved by further applying an adhesive or primer coating on the surface of the laminate layer(s). For example, U.S. Pat. No. 4,865,711 describes a film or sheet with improved bondability, which has a thin layer of carbon deposited on one or both surfaces. Other exemplary adhesives or primers may include silanes, poly(allyl amine) based primers (see e.g., U.S. Pat. Nos. 5,411,845; 5,770,312; 5,690,994; and 5,698,329), and acrylic based primers (see e.g., U.S. Pat. No. 5,415,942). The adhesive or primer coating may take the form of a monolayer of the adhesive or primer and have a thickness of about 0.0004 to about 1 mil (about 0.00001 to about 0.03 mm), or preferably, about 0.004 to about 0.5 mil (about 0.0001 to about 0.013 mm), or more preferably, about 0.004 to about 0.1 mil (about 0.0001 to about 0.003 mm).

In addition, when a polymeric film is incorporated as an outside surface layer of the solar cell module, the outside surface may be provided with an abrasion resistant hard coat. Any material known for use in abrasion resistant hard coats may be used. For example, the hard coat may comprise polysiloxanes or cross-linked (thermosetting) polyurethanes. Also suitable are oligomeric-based coatings, such as those described in U.S. Patent Application Publication No. 2005/0077002, which are prepared by the reaction of (A) a hydroxyl-containing oligomer with isocyanate-containing oligomer or (B) an anhydride-containing oligomer with epoxide-containing compound. In certain modules, the hard coat may comprise a polysiloxane abrasion resistant coating, such as those described in U.S. Pat. Nos. 4,177,315; 4,469,743; 5,415,942; and 5,763,089.

Any suitable lamination process may be used to prepare the solar cell modules. In one suitable process, the component layers of the solar cell module in sheet form are stacked in the desired order to form a pre-lamination assembly. The assembly is then placed into a bag capable of sustaining a vacuum (“a vacuum bag”), and the air is drawn out of the bag by a vacuum line or other means. The bag is sealed while the vacuum is maintained (e.g., at least about 27-28 in Hg (689-711 mm Hg)), and the sealed bag is placed in an autoclave and the pressure is raised to about 150 to about 250 psi (about 11.3 to about 18.8 bar), a temperature of about 130° C. to about 180° C., or about 120° C. to about 160° C., or about 135° C. to about 155° C., or about 145° C. to about 155° C., for about 10 to about 50 min, or about 20 to about 45 min, or about 20 to about 40 min, or about 25 to about 35 min. A vacuum ring may be substituted for the vacuum bag. One type of suitable vacuum bag is described within U.S. Pat. No. 3,311,517. Following the heat and pressure cycle, the air in the autoclave is cooled without adding additional gas to maintain pressure in the autoclave. After about 20 min of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 min, and thereafter, the heated assembly is passed through a set of nip rolls so that the air in the void spaces between the individual layers may be squeezed out, and the edge of the assembly sealed. The assembly at this stage is referred to as a pre-press.

The pre-press may then be placed in an air autoclave where the temperature is raised to about 120° C. to about 160° C., or about 135° C. to about 160° C., at a pressure of about 100 to about 300 psi (about 6.9 to about 20.7 bar), or preferably about 200 psi (13.8 bar). These conditions are maintained for about 15 to about 60 min, or about 20 to about 50 min, after which the air is cooled while no further air is introduced to the autoclave. After about 20 to about 40 min of cooling, the excess air pressure is vented and the laminated products are removed from the autoclave.

The solar cell modules may also be produced through non-autoclave processes. Suitable non-autoclave processes are described, e.g., in U.S. Pat. Nos. 3,234,062; 3,852,136; 4,341,576; 4,385,951; 4,398,979; 5,536,347; 5,853,516; 6,342,116; and 5,415,909, U.S. Patent Publication No. 20040182493, European Patent No. EP1235683 B1, and PCT Patent Publication Nos. WO9101880 and WO03057478. Generally, the non-autoclave processes include heating the pre-lamination assembly and the application of vacuum, pressure or both. For example, the assembly may be successively passed through heating ovens and nip rolls.

In this connection, the encapsulant sheets are generally supplied as sheets having a substantially uniform thickness. When the encapsulant sheets are laid up with the solar cell assembly in the pre-press assembly, there may be gaps or voids in which portions of the solar cell assembly are not in contact with the encapsulant sheets. During the lamination process, however, the polymeric encapsulant sheets melt or soften to some degree. Under the pressure that is applied during the process, the encapsulant also flows around the surface peaks or contours of the solar cell assembly. Thus, any voids between the solar cell assembly and the encapsulant sheets are filled during the lamination process to provide solar cell modules in which the encapsulant is in good contact with the solar cell assembly.

If desired, the edges of the laminated solar cell module may be sealed to reduce moisture and air intrusion and potential degradative effects on the efficiency and lifetime of the solar cells. Suitable edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The following examples are provided to describe the invention in further detail. These examples, which set forth a preferred mode presently contemplated for carrying out the invention, are intended to illustrate and not to limit the invention.

### EXAMPLES

In each of the following examples, two sets of identical glass laminates were prepared, with one set subjected to a Pummel adhesion test, moisture test, and stress test shortly after lamination and the other set subjected to the Pummel adhesion, moisture, and stress tests after undergoing 50 thermal cycles in which the temperature is alternated between −40° C. and 85° C., in accordance to IEC 61646.

Each of the glass laminates prepared in Example E1 has dimensions of 15×15 cm and a layered structure of “glass sheet 1/ionomeric interlayer sheet/glass sheet 2”, wherein “glass sheet 1” is a 2.3 mm thick glass sheet manufactured by PPG Industries, Pittsburgh, Pa.; “glass sheet 2” is a 0.7 mm thick glass sheet manufactured by Euro-Tech GmbH (Germany); and “ionomeric interlayer sheet” is a 35 mil (0.89 mm) thick DuPont PV5300 ionomer resin encapsulant sheet available from E.I. DuPont de Nemours & Co. of Wilmington, Del. (hereinafter “DuPont”). The glass laminates prepared in Example E2 are similar to those prepared in Example E1, except that a pair of 20 cm long, 2 mm wide, and 100 μm thick wires were further embedded between “glass sheet 1” and “ionomeric interlayer sheet” along opposite sides of the laminate and about 2 cm away from the respective edges. The glass laminates prepared in Example E3 were similar to those prepared in Example E2, except that each of the two 20 cm long, 2 mm wide, and 100 μm thick wires has one end protruding from the laminate.

Each of the glass laminates E1, E2 and E3 was prepared by placing the “glass sheet 1/wires if used/ionomeric interlayer sheet/glass sheet 2” assembly in a disposable vacuum bag, maintaining the assembly within the vacuum bag under vacuum for about 20 minutes at room temperature, placing the vacuum bag that contained the assembly into an oven that was set at 90° C. for another 20 minutes, removing the assembly from the vacuum bag, and finally subjecting the assembly to an autoclave process that was conducted under conditions that provided a maximum temperature of 145° C. for 20 minutes and a maximum plateau pressure of 8.5 bar.

The pummel adhesion value of each laminate was determined by first equilibrating the sample laminate at 25° C.+/−5° C. for 1 hour or more and then pummeling the laminate with a 0.5 kg flat headed hammer. The laminate was pummeled in a pattern of rows with 1.25 cm intervals between impact location and 2 cm intervals between rows. The pummel adhesion rating was assigned based on the amount of pulverized glass remaining adhered to the interlayer according to the arbitrary scale set forth in Table 1.

TABLE 1

| Percentage of Glass Removed | |
|---|---|
| from the Laminate Surface | Pummel Adhesion Rating |
| 100 | 0 |
| 95 | 1 |
| 90 | 2 |
| 80 | 3 |
| 60 | 4 |
| 40 | 5 |
| 20 | 6 |
| 10 | 7 |
| 5 | 8 |
| 2 | 9 |
| 0 | 10 |

Two Pummel adhesion values were measured for each laminate, with the “IN” value determined by hammering the laminate on “glass sheet 1” and the “OUT” value determined by hammering the laminate on “glass sheet 2”.

The level of moisture increase of each laminate was determined using a Spectrum BX FTIR Spectrometer from Perkin Elmer, Waltham, Mass. Specifically, a transmission near infrared (NIR) spectrum was recorded and the moisture band between 1880 and 1990 nm was integrated. The integrated area was then compared to moisture standards to calculate the moisture content in the sample. Moisture gain values were recorded in two positions for each laminate. “Position 1” was a location about 1 cm away from the edge of the laminate, and “Position 2” was a location close to the center of the laminate. In Examples E2 and E3, Position 1 was between the edge and a wire.

The stress developed on each of the laminates was determined visually by observation under crossed polarized lights at angles varying between 180 and 90 degrees. No rainbow-like features indicating stress were observed in the sample laminates.

The data set forth in Table 2 indicate that glass laminates employing a 0.7 mm thick thin glass sheet and a 35 mil (0.89 mm) ionomeric interlayer sheet have good pummel adhesion levels, good moisture resistance, and low stress. This demonstrates that it is feasible to use thin glass sheets as one or both of the outer protective layers in a glass laminate having an ionomeric interlayer, thus reducing the weight of the laminate while maintaining its physical strength.

TABLE 2

| | Before Thermal Cycle | | | | | After Thermal Cycle | | | | |
|---|---|---|---|---|---|---|---|---|---|---|
| | Pummel | | | | | Pummel | | | | |
| Sam- | Adhesion | | Moisture | | | Adhesion | | Moisture | | |
| ple | In | Out | Pos 1 | Pos 2 | Stress | In | Out | Pos 1 | Pos 2 | Stress |
| E1 | 5 | 7 | 0 | 0 | No | 5 | 7 | 0.05 | 0 | No |
| E2 | 5 | 7 | 0 | 0 | No | 5 | 7 | 0.03 | 0.07 | No |
| E3 | 5 | 7 | 0.09 | 0.01 | No | 5 | 7 | 0.06 | 0.07 | No |

### Comparative Example C1 and Examples E4 and E5

The stress development and deflection in the following hypothetical glazing constructs is calculated by non-linear finite element modeling (FEM) stress analysis. In Example C1, the glazing construct is a 6.5 mm thick polycarbonate sheet. In Example E4, the glazing construct is a laminate of one DuPont PV5300 ionomeric encapsulant sheet (4.56 mm in thickness), available from DuPont, laminated between two thin glass sheets (1 mm in thickness). In Example E5, the glazing construct is a laminate of one DuPont PV5300 ionomeric encapsulant sheet (3.04 mm in thickness) laminated between two thin glass sheets (1 mm in thickness). The glazing construct in each of these Examples has a dimension of 1000×800 mm and is supported on four sides. A uniform load of 2 kPa is applied. The Young's modulus and Poisson ratio for each component of the glazing constructs are listed in Table 3.

TABLE 3

| | Young's Modulus | |
|---|---|---|
| Material | (MPa) | Poisson Ratio |
| Glass | 70,000^{a} | 0.23^{b} |
| DuPont PV5300 sheet | 15^{c}; 300^{d} | 0.499^{c} |
| Polycarbonate sheet | 2,300^{e} | 0.4^{e} |

Notes:
^{a}Measured in accordance with ENISO1288;
^{b}measured in accordance with EN843;
^{c}measured in accordance with ASTM D5026 at 40° C. and 1 day of load duration;
^{d}measured in accordance with ASTM D5026 at 30° C. and 1 minute of load duration; and
^{e}measured in accordance with ISO527.

The maximum stress development and deflection of each of the laminates is calculated using SJ-MEPLA (Version 3.0.4 by SJ-Software, Germany) The resulting values are reported in Table 4.

TABLE 4

| | Maximum Stress | Maximum Deflection |
|---|---|---|
| Sample | (MPa) | (mm) |
| C1 | 5.25 | 27.15 |
| E4 | 20.49 | 7.39 |
| E5 | 23.27 | 9.69 |

These results demonstrate that laminates with thin (1 mm) glass sheets and ionomeric interlayers will have higher strength and will show less deflection when compared to polycarbonate sheets.

### Example E6

A series of laminates with a structure of “thin glass sheet (1.1 mm)/ionomeric sheet (60 mil)/thin glass sheet (1.1 mm)” were prepared. The thin glass sheets were UFF™ thin glass obtained from Nippon Sheet Glass Company, Ltd. (Tokyo, Japan) and the ionomer sheets were PV5300 sheets obtained from DuPont.

The laminates were then subjected to several European Security Standard tests. In the EN356-P2A test, a steel ball (100 mm in diameter and 4.11 kg in weight) was dropped onto the Laminate structure three times from a height of 3 m. The laminates passed this test, as they were not penetrated after the third impact. In the EN356-P3A test, a steel ball (100 mm in diameter and 4.11 kg in weight) was dropped onto the laminate structure three times from a height of 6 m. A first laminate failed this test as the steel ball penetrated the laminate at the third drop; however, a second laminate passed with no penetration after the third drop. Finally, in the EN356-P4A test, a steel ball (100 mm in diameter and 4.11 kg in weight) was dropped onto the laminate structure three times from a height of 9 m. The laminate failed this test as the steel ball penetrated the laminate at the second drop.

### Examples E7 to E14

By a similar lamination process used above, a series of “glass 1/ionomeric interlayer/glass 2” laminates were prepared. The structures of these laminates are set forth in Table 5. The laminates were subjected to the JIS R3205 ball drop test, in which a steel ball with a diameter of 63 mm and a weight of 1.04 kg was first dropped from a height of 120 cm onto the laminate with a dimension of 610×610 mm. If no destruction occurred, the drop was repeated from a height of 150 cm, then 190 cm, then 240 cm, then 300 cm, then 380 cm, and then 480 cm. The results of this experiment are also recorded in Table 5.

TABLE 5

| | Sample Structure | | | | | | | | | | |
|---|---|---|---|---|---|---|---|---|---|---|---|
| | | Ionomer | | | Ball Drop Height (cm) | | | | | | Crack or |
| | Glass 1^{a} | Interlayer^{b} | Glass 2^{a} | | (No Break: OK; Break: X) | | | | | | Delamination |
| Sample # | (mm) | (mil) | (mm) | Test # | 120 | 150 | 190 | 240 | 300 | 380 | of interlayer |
| E7 | 1.1 | 60 | 1.1 | 1 | OK | OK | X | | | | No |
| | | | | 2 | X | | | | | | No |
| | | | | 3 | OK | X | | | | | No |
| E8 | 1.1 | 35 | 1.1 | 1 | OK | OK | OK | X | | | No |
| | | | | 2 | OK | OK | OK | OK | OK | X | N/A |
| | | | | 3 | X | | | | | | No |
| E9 | 0.7 | 60 | 0.7 | 1 | X | | | | | | No |
| | | | | 2 | OK | OK | X | | | | No |
| | | | | 3 | OK | X | | | | | No |
| E10 | 0.7 | 35 | 0.7 | 1 | OK | OK | OK | OK | X | | N/A |
| | | | | 2 | OK | OK | OK | OK | X | | N/A |
| | | | | 3 | OK | OK | X | | | | N/A |
| E11 | 0.55 | 60 | 0.55 | 1 | OK | OK | X | | | | N/A |
| | | | | 2 | OK | OK | OK | OK | X | | No |
| | | | | 3 | X | | | | | | No |
| E12 | 0.55 | 35 | 0.55 | 1 | X | | | | | | No |
| | | | | 2 | Ok | OK | OK | X | | | No |
| | | | | 3 | X | | | | | | No |
| E13 | 0.3 | 60 | 0.3 | 1 | X | | | | | | No |
| | | | | 2 | OK | X | | | | | No |
| | | | | 3 | OK | X | | | | | No |
| E14 | 0.3 | 35 | 0.3 | 1 | OK | OK | X | | | | No |
| | | | | 2 | X | | | | | | No |
| | | | | 3 | X | | | | | | No |

^{a}The glass sheets used here were UFF ™ thin glass obtained from Nippon Sheet Glass Company, Ltd.
^{b}The ionomeric interlayer sheets were PV5300 sheets obtained from DuPont.

### Examples E15 and E16

In Example E15, glass laminates with ionomeric interlayers are prepared. The laminates are exposed to outdoor natural weathering in Florida for 72 months and to outdoor accelerated weathering in Arizona for 96 months equivalent exposure. No delamination, visual defects, edge clouding, or undesired haze change is observed in the laminates after the weathering. Moreover, the laminates' tensile strength remains strong after 4500 hours of laboratory accelerated weathering.

In Example E16, glass laminates with ionomeric interlayers or PVB interlayers are prepared. After humidity freeze testing, no visual defects, delaminations, discoloration or adhesion loss is observed in those laminates with ionomeric interlayers. In laminates with PVB interlayers, however, both edge cloud and delamination are observed after the humidity freeze testing.

### Example E17

The moisture ingress profile of EVA interlayers, PVB interlayers, and ionomeric interlayers laminated between two glass lites (3.2 mm in thickness) has been obtained by Kapur et al, using an FTIR method and using the method of ASTM D7191. See Kapur et al., Proceedings of the Photovoltaic Specialists Conference (PVSC), 2009 34th IEEE; Digital Object Identifier: 10.11091 PVSC.2009.5411235; Publication Year: 2009, Page(s): 001210-001214. The data obtained by Kapur et al. demonstrate that moisture ingress into the ionomeric interlayers is less moisture ingress into the EVA and PVB interlayers. It is also believed that moisture ingress into a glass laminate is not significantly affected by the thickness of the glass layers, if the thickness is at least about 0.1 mm. Accordingly, it is predicted that laminates of ionomeric interlayers between two thin glass sheets have a moisture ingress that is less than, and therefore superior to, that of the PVB laminates studied by Kapur et al.

While certain of the preferred embodiments of the present invention have been described and specifically exemplified above, it is not intended that the invention be limited to such embodiments. It is to be understood, moreover, that even though numerous characteristics and advantages of the present invention have been set forth in the foregoing description, together with details of the structure and function of the invention, the disclosure is illustrative only, and changes may be made in detail, especially in matters of shape, size and arrangement of parts, within the principles of the invention to the full extent indicated by the broad general meaning of the terms in which the appended claims are expressed.

What is claimed is:

1. A solar cell module comprising, as laminated layers, (A) a solar cell assembly comprising one or a plurality of solar cells, (B) a first ionomeric encapsulant layer comprising a first ionomer composition, and (C) a first outer protective layer comprising a first thin glass sheet having a thickness of less than 1.5 mm.

2. The solar cell module of claim 1, wherein the solar cells are wafer-based solar cells comprising one or both of monocrystalline silicon (c-Si), multi-crystalline silicone (mc-Si) or wherein the solar cells are thin film solar cells comprising one or more materials selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductors; and wherein, when the solar cells are thin film solar cells, the solar cell assembly further comprises a substrate or superstrate upon which the thin film solar cells are deposited.

3. The solar cell module of claim 1, wherein the first ionomer composition has a Young's modulus of about 200 to about 600 MPa, as determined in accordance with ASTM D5026 at 30° C. and 1 minute of load duration.

4. The solar cell module of claim 1, wherein the first ionomer composition comprises an ionomer that is an ionic neutralized derivative of a precursor acid copolymer comprising copolymerized units of an α-olefin having 2 to 10 carbon atoms and about 18 to about 30 wt % of copolymerized units of an α,β-ethylenically unsaturated carboxylic acid having 3 to 8 carbons, based on a total weight of the precursor acid copolymer, and wherein about 5% to about 90% of a total content of the α,β-ethylenically unsaturated carboxylic acid present in the precursor acid copolymer have been neutralized.

5. The solar cell module of claim 4, wherein the precursor acid copolymer comprises about 20 to about 25 wt % of copolymerized units of the α,β-ethylenically unsaturated carboxylic acid, and wherein about 10% to about 60% of the total content of the α,β-ethylenically unsaturated carboxylic acid present in the precursor acid copolymer have been neutralized.

6. The solar cell module of claim 1, wherein the first encapsulant layer has an average thickness of 1 to about 120 mils (about 0.025 to about 3 mm).

7. The solar cell module of claim 1, wherein the thin glass sheet has a thickness of about 0.1 to about 0.8 mm.

8. The solar cell module of claim 1, wherein the first encapsulant layer has a first side that is laminated directly to the solar cell assembly and a second side that is laminated directly to the first outer protective layer.

9. The solar cell module of claim 8, which further comprises, as laminated layers, (D) a second encapsulant layer having two sides and laminated to the side of the solar cell assembly that is opposite from the side to which the first encapsulant layer is laminated; and (E) a second outer protective layer that is laminated to the side of the second encapsulant layer that is opposite from the side to which the solar cell assembly is laminated.

10. The solar cell module of claim 9, wherein the second encapsulant layer comprises one or more polymeric materials selected from the group consisting of copolymers of an α-olefin and an α,β-ethylenically unsaturated carboxylic acid, ionomers, poly(ethylene vinyl acetates), poly(vinyl acetals), polyurethanes, poly(vinyl chlorides), polyethylenes, polyolefin block copolymer elastomers, copolymers of an α-olefin and an α,β-ethylenically unsaturated carboxylic acid, silicone elastomers, and epoxy resins.

11. The solar cell module of claim 9, wherein the second outer protective layer comprises one or more materials selected from the group consisting of (i) glass sheets; (ii) polymeric sheets comprising one or more polymers selected from the group consisting of polycarbonates, acrylics, polyacrylates, cyclic polyolefins, polystyrenes, polyamides, polyesters, and fluoropolymers; and (iii) polymeric films comprising one or more polymers selected from the group consisting of polyesters, polycarbonates, polyolefins, norbornene polymers, polystyrenes, styrene-acrylate copolymers, acrylonitrile-styrene copolymers, polysulfones, nylons, polyurethanes, acrylics, cellulose acetates, cellophanes, poly(vinyl chlorides), and fluoropolymers.

12. The solar cell module of claim 9, wherein the second encapsulant layer comprises a second ionomer composition, and wherein the first and second ionomer composition are the same or different.

13. The solar cell module of claim 9, wherein the second outer protective layer comprises a second thin glass sheet having a thickness of less than 2.0 mm or of about 1.5 mm or less.

14. The solar cell module of claim 9, wherein the solar cell assembly has a smaller lateral area than the encapsulant layers and outer protective layers, and wherein the first and second encapsulant layers are bonded together in areas that are outside of peripheral edges of the solar cell assembly.

15. The solar cell module of claim 14, which further comprises at least one mounting device, wherein the at least one mounting device is positioned outside the peripheral edges of the solar cell assembly and has a first portion that is laminated between the first and second encapsulant layers and a second portion that is protruding outward from peripheral edges of the solar cell module.

16. The solar cell module of claim 15, wherein the at least one mounting device further comprises a third portion that forms a cover over the portion of the peripheral edge from which it protrudes.

17. The solar cell module of claim 15, wherein the second portion of the at least one mounting device comprises at least one anchoring means.

18. The solar cell module of claim 15, which comprises two mounting devices, and wherein the mounting devices are positioned on opposite peripheral edges of the solar cell module.

19. The solar cell module of claim 15, which comprises four mounting devices, and wherein two of the mounting devices are positioned on a single edge of the solar cell module, and two of the mounting devices are positioned on the opposite peripheral edge of the solar cell module.

20. The solar cell module of claim 15, which comprises four mounting devices and wherein each of the mounting devices is positioned on a different peripheral edge of the solar cell module.

21. The solar cell module of claim 15, wherein the at least one mounting device is made of metal or plastic.

22. The solar cell module of claim 21, wherein the at least one mounting device comprises a metal selected from the group consisting of steel, aluminum, titanium, brass, lead, chrome, copper, and alloys thereof.
